(19) United States
(12) Patent Application Publication
(10) Pub. No.: US 2024/0150221 A1
(43) Pub. Date: May 9, 2024

(54) COVER SUBSTRATES FOR AN ELECTRONIC DEVICE INCLUDING POST-CONSUMER RECYCLED CONTENT AND METHODS OF MANUFACTURING THE SAME

(71) Applicant: CORNING INCORPORATED, Corning, NY (US)

(72) Inventors: Carol Ann Click, Corning, NY (US); Mathieu Gerard Jacques Hubert, Corning, NY (US)

(21) Appl. No.: 18/383,535

(22) Filed: Oct. 25, 2023

Related U.S. Application Data
(60) Provisional application No. 63/423,847, filed on Nov. 9, 2022.

(51) Int. Cl. C03C 3/097; C03B 32/02; C03C 1/00; C03C 10/00; C03C 21/00; H05K 5/03

(52) U.S. Cl. CPC C03C 3/097; C03B 32/02; C03C 1/002; C03C 10/00; C03C 21/002; H05K 5/03; C03C 2204/00

(57) ABSTRACT

A cover substrate for an electronic device including greater than or equal to 1% by weight post-consumer recycled cover substrate. A method of forming the cover substrate including the steps of (i) determining the composition of the post-consumer recycled cover substrate, (ii) determining the maximum amount of the post-consumer recycled cover substrate that can be added to a predetermined batch without causing the resulting cover substrate to fall out of specification, and (iii) forming the cover substrate from the combined recycled post-consumer cover substrate and the predetermined batch. Additionally, a method that includes steps of (i) determining the composition of the post-consumer recycled cover substrate, (ii) determining a target weight percentage of the post-consumer recycled cover substrate in a cover substrate, and (iii) determining weight percentages of other oxides to be added to the target weight percentage for the resulting combination to produce the cover substrate with a desired composition.

This application claims the benefit of priority to U.S. Provisional Patent Application No. 63/423,847 filed Nov. 9, 2022, the content of which is relied upon and incorporated herein by reference in its entirety.

### FIELD OF THE INVENTION

The present disclosure relates to cover substrates for electronic devices that include post-consumer recycled content and methods to manufacture the same.

### BACKGROUND

Consumer electronic devices sometimes include one or more cover substrates that separate a display, touch-screen functionality, and internal electronics of the consumer electronic device from an external environment. The cover substrate is sometimes transparent, such as when cover substrate covers the display and touch-screen functionality. The cover substrate is sometimes opaque, such as when the cover substrate covers internal electronics but not the display. The cover substrate is sometimes chemically toughened via an ion-exchange process. The ion-exchange process changes the composition of the cover substrate at a region contiguous with a primary surface of the substrate. Heretofore, such ion-exchanged cover substrates have been considered to be unsuitable for recycling and reincorporation into newly made cover glass, because of the change in composition that the ion-exchange process causes. Cover substrates typically have compositional specifications that do not allow for much deviation from a target composition, because minor compositional changes can greatly affect optical performance, ability to be ion-exchanged, and mechanical resistance to scratches and abrasions, among other things. The differing composition of the ion-exchanged cover substrate, if recycled post-consumer, could cause too much deviation from the target composition. Consequently, to date, post-consumer cover substrates have not been recycled and formed into new cover substrates.

### SUMMARY

The present disclosure addresses those problems and satisfies a general desire to recycle post-consumer cover substrate, in general, by (i) determining the composition of the recycled post-consumer cover substrate, (ii) determining the maximum amount of the recycled post-consumer cover substrate that can be added to a predetermined batch of oxides without causing the resulting cover substrate to fall out of specification, and (iii) forming the cover substrate from the combined recycled post-consumer cover substrate and the predetermined batch of oxides. Alternatively, the present disclosure addresses those problems, in general, by (i) determining the composition of the recycled post-consumer cover substrate, (ii) determining a target weight percentage of the recycled post-consumer cover substrate in the newly manufactured cover substrate, (iii) determining weight percentages of one or more oxides to be added to the target weight percentage of the recycled post-consumer cover substrate in order for the resulting combination to produce the cover substrate with a desired composition. In any event, the newly manufactured cover substrate includes a significant weight percentage of recycled post-consumer cover substrate. The newly manufactured cover substrate can be ion-exchanged.

According to a first aspect of the present disclosure, a cover substrate for an electronic device comprises: greater than or equal to 1% by weight post-consumer recycled cover substrate.

According to a second aspect of the present disclosure, the cover substrate of the first aspect further comprises: (i) a first primary surface; (ii) a second primary surface that faces in a generally opposite direction as the first primary surface; and (iii) a thickness between the first primary surface and the second primary surface, the thickness being within a range of from 0.05 mm to 3.0 mm.

According to a third aspect of the present disclosure, the cover substrate of any one of the first through second aspects further comprises a composition comprising (on an oxide basis): greater than 50% by weight SiO₂; greater than 5% by weight Al₂O₃; and at least one of Li₂O and Na₂O.

According to a fourth aspect of the present disclosure, the cover substrate of any one of the first through second aspects further comprises a composition comprising (on an oxide basis): from 50% by weight to 80% by weight SiO₂; from 5% by weight to 35% by weight Al₂O₃; and at least one of Li₂O and Na₂O.

According to a fifth aspect of the present disclosure, the cover substrate of any one of the first through second aspects further comprises (i) a bulk and (ii) a composition at the bulk that comprises (on an oxide basis): from 50% by weight to 70% by weight SiO₂; from 15% by weight to 30% by weight Al₂O₃; from 1.5% by weight to 8% by weight B₂O₃; and from 1% by weight to 15% by weight Na₂O.

According to a sixth aspect of the present disclosure, the cover substrate of any one of the first through second aspects further comprises (i) a bulk and (ii) a composition at the bulk that comprises (on an oxide basis): from 50% by weight to 80% by weight SiO₂; from 5% by weight to 25% by weight Al₂O₃; from 1% by weight to 10% by weight P₂O₅; and from 1% by weight to 15% by weight Li₂O.

According to a seventh aspect of the present disclosure, the cover substrate of any one of the first through sixth aspects further comprises a glass composition or a glass-ceramic composition, wherein, the post-consumer recycled cover substrate comprises a glass composition or a glass-ceramic composition.

According to an eighth aspect of the present disclosure, the cover substrate of any one of the first through seventh aspects is presented, wherein the cover substrate comprises a compressive stress region.

According to a ninth aspect of the present disclosure, the cover substrate of any one of the first through eighth aspects is presented, wherein the cover substrate comprises a composition that has a greater weight percentage of sodium ions at or near a primary surface of the cover substrate than at or near a bulk of the cover substrate.

According to a tenth aspect of the present disclosure, any one of the first through ninth aspects is presented, wherein the cover substrate exhibits an axial transmission of greater than 90% for a wavelength of electromagnetic radiation within the range of 420 nm to 800 nm.

According to an eleventh aspect of the present disclosure, any one of the first through tenth aspects is presented, wherein the cover substrate comprises from 2% by weight to 20% by weight post-consumer recycled cover substrate.

According to a twelfth aspect of the present disclosure, a method of manufacturing a cover substrate of an electronic device comprises: (i) preparing a batch comprising one or more glass-forming oxides and greater than 1% by weight of post-consumer recycled cover substrate and (ii) forming a cover substrate from the batch.

According to a thirteenth aspect of the present disclosure, the method of the twelfth aspect further comprises: forming a cover substrate from the batch.

According to a fourteenth aspect of the present disclosure, the method of any one of the twelfth through thirteenth aspects further comprises ceramming the cover substrate to form the cover substrate comprising a glass-ceramic composition.

According to a fifteenth aspect of the present disclosure, the method of any one of the twelfth through fourteenth aspects is presented, wherein the post-consumer recycled cover substrate had been subjected to an ion-exchange process.

According to a sixteenth aspect of the present disclosure, the method of any one of the twelfth through fifteenth aspects is presented, wherein the post-consumer recycled cover substrate, before the batch is prepared, comprises (i) a first primary surface, a second primary surface, and a bulk disposed between the first primary surface and the second primary surface and (ii) a composition that comprises an alkali oxide that is a greater percentage of the composition at or near the first primary surface than at the bulk.

According to a seventeenth aspect of the present disclosure, the method of any one of the twelfth through sixteenth aspects is presented, wherein the batch comprises from 2% by weight to 20% by weight of the post-consumer recycled cover substrate.

According to an eighteenth aspect of the present disclosure, the method of any one of the twelfth through seventeenth aspects is presented, wherein weight percentages (on an oxide basis) of SiO₂, Al₂O₃, and at least one of B₂O₃ and P₂O₅ in a composition of the cover substrate formed from the batch differ by 1% by weight or less from weight percentages (on an oxide basis) of SiO₂, Al₂O₃, and the at least one of B₂O₃ and P₂O₅ in a composition of the post-consumer recycled cover substrate.

According to a nineteenth aspect of the present disclosure, the method of any one of the twelfth through eighteenth aspects is presented, wherein (i) the cover substrate comprises a glass composition or a glass-ceramic composition and (ii) the post-consumer recycled cover substrate comprises a glass composition or a glass-ceramic composition.

According to a twentieth aspect of the present disclosure, a method of manufacturing a cover substrate of an electronic device comprises: (i) determining a recycled composition of a post-consumer recycled cover substrate, the recycled composition comprising SiO₂ and one or more alkali oxides; (ii) determining a maximum weight percentage of the post-consumer recycled cover substrate that can be added to a predetermined batch comprising a predetermined composition, the predetermined composition comprising SiO₂, to form a target batch comprising a target composition comprising SiO₂ and one or more alkali oxides, without a weight percentage of any component of the target composition exceeding a predetermined limit; (iii) combining the maximum weight percentage or less of the post-consumer recycled cover substrate with the predetermined batch thus forming the target batch; and (iv) forming a cover substrate from the target batch.

According to a twenty-first aspect of the present disclosure, the method of the twentieth aspect further comprises subjecting the cover substrate formed from the target batch to an ion-exchange process, wherein, the cover substrate after the ion-exchange process comprises (i) a compressive stress region and (ii) a composition that has a greater weight percentage of potassium ions at or near a primary surface of the cover glass than at or near a bulk of the cover substrate.

According to a twenty-second aspect of the present disclosure, the method of any one of the twentieth through twenty-first aspects further comprises ceramming the cover substrate formed from the target batch.

According to a twenty-third aspect of the present disclosure, the method of any one of the twentieth through twenty-second aspects is presented, wherein (i) the one or more alkali oxides of the recycled composition comprises Na₂O and (ii) the predetermined batch does not include any intentionally added Na₂O.

According to a twenty-fourth aspect of the present disclosure, the method of any one of the twentieth through twenty-second aspects is presented, wherein (i) the one or more alkali oxides of the recycled composition comprises a weight percentage of Na₂O; (ii) the predetermined composition of the predetermined batch comprises a weight percentage of Na₂O; and (iii) the weight percent of Na₂O of the recycled composition is greater than the weight percentage of Na₂O of the predetermined composition.

According to a twenty-fifth aspect of the present disclosure, the method of any one of the twentieth through twenty-fourth aspects is presented, wherein (i) the one or more alkali oxides of the recycled composition and the one or more alkali oxides of the predetermined composition both comprise K₂O and (ii) the recycled composition has a weight percentage of K₂O that is greater than a weight percentage of K₂O in the predetermined composition.

According to a twenty-sixth aspect of the present disclosure, the method of any one of the twentieth through twenty-fifth aspects is presented, wherein (i) the one or more alkali oxides of the recycled composition and the one or more alkali oxides of the predetermined composition both comprise Li₂O and (ii) the recycled composition has a weight percentage of Li₂O that is less than a weight percentage of Li₂O in the predetermined composition.

According to a twenty-seventh aspect of the present disclosure, the method of any one of the twentieth through twenty-sixth aspects is presented, wherein the target batch comprises greater than or equal to 1% by weight of the post-consumer recycled cover substrate.

According to a twenty-eighth aspect of the present disclosure, the method of any one of the twentieth through twenty-seventh aspects is presented, wherein the target batch comprises from 2% by weight to 20% by weight of the post-consumer recycled cover substrate.

According to a twenty-ninth aspect of the present disclosure, the method of any one of the twentieth through twenty-eighth aspects is presented, wherein weight percentages (on an oxide basis) of SiO₂, Al₂O₃, and at least one of B₂O₃ and P₂O₅ of the target composition differ by 1% by weight or less from weight percentages (on an oxide basis) of SiO₂, Al₂O₃, and at least one of B₂O₃ and P₂O₅ in the recycled composition of the post-consumer recycled cover substrate.

According to a thirtieth aspect of the present disclosure, the method of any one of the twentieth through twenty-ninth aspects is presented, wherein the cover substrate comprises (i) a bulk and (ii) a composition at the bulk that comprises (on an oxide basis): from 50% by weight to 80% by weight SiO₂; from 5% by weight to 35% by weight Al₂O₃; and at least one of Li₂O and Na₂O.

According to a thirty-first aspect of the present disclosure, the method of any one of the twentieth through thirtieth aspects is presented, wherein the cover substrate exhibits an axial transmission of greater than 90% for a wavelength of electromagnetic radiation within a range of 420 nm to 800 nm.

According to a thirty-second aspect of the present disclosure, a method of manufacturing a cover substrate of an electronic device comprises: (i) determining a recycled composition of a post-consumer recycled cover substrate, the recycled composition comprising one or more oxides; (ii) determining a target composition for a target batch to form a cover substrate, the target composition comprising one or more oxides; (iii) determining a desired weight percentage of the post-consumer recycled cover substrate in the cover substrate; (iv) determining a remediating composition of a remediating batch that, when combined with the desired weight percentage of the post-consumer recycled cover substrate, forms the target batch comprising the target composition; (v) forming the target batch comprising the target composition with the desired weight percentage of the post-consumer recycled cover substrate and a remaining weight percentage of the remediating batch; and (vi) forming the cover substrate from the target batch.

According to a thirty-third aspect of the present disclosure, the method of the thirty-second aspect is presented, wherein both the post-consumer recycled cover substrate and the cover substrate are glasses or glass-ceramics.

### BRIEF DESCRIPTION OF THE DRAWINGS

In the Drawings:

FIG. 1 is a perspective view of a cover substrate including post-consumer recycled cover substrate;

FIG. 2 is a cross-sectional view of the cover substrate of FIG. 1, illustrating that the cover substrate can be strengthened to include compressive stress regions contiguous with primary surfaces of the cover substrate;

FIG. 3 is a schematic diagram that illustrates a used electronic device with the post-consumer recycled cover substrate, the post-consumer recycled cover substrate removed from the electronic device, total raw materials that includes the post-consumer recycled cover substrate and new raw materials, the cover substrate of FIG. 1 formed from the total raw materials, and an electronic device that includes the cover substrate of FIG. 1;

FIG. 4 is a flow diagram of a method of manufacturing the cover substrate of FIG. 1;

FIG. 5 is a flow diagram of another method of manufacturing the cover substrate of FIG. 1;

FIG. 6 is a flow diagram of another method of manufacturing the cover substrate of FIG. 1; and

FIG. 7, pertaining to an Example 1, is a graph that plots (i) axial transmission percentage through a cover substrate of the present disclosure that includes 5% by weight post-consumer recycled cover substrate as a function of wavelength of electromagnetic radiation and (ii) axial transmission percentage through a comparative cover substrate that does not include any post-consumer recycled cover substrate as a function of wavelength of electromagnetic radiation.

### DETAILED DESCRIPTION

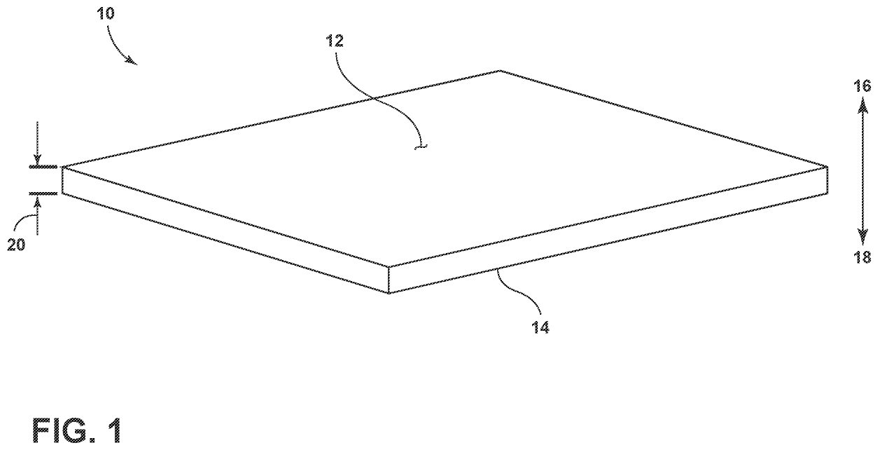

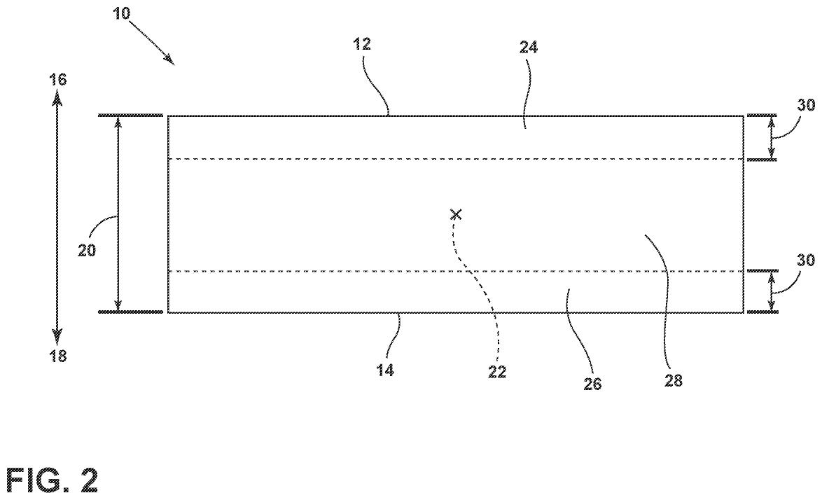

Referring now to FIGS. 1 and 2, a cover substrate 10 includes a first primary surface 12 and a second primary surface 14. The first primary surface 12 and the second primary surface 14 face in generally opposite directions 16, 18, respectively. The first primary surface 12 and the second primary surface 14 can be generally planar, but need not be. The cover substrate 10 further includes a thickness 20. The thickness 20 extends between the first primary surface 12 and the second primary surface 14. In embodiments, the thickness 20 is 0.5 mm, 0.6 mm, 0.7 mm, 0.8 mm, 0.9 mm, 1.0 mm, 1.1 mm, 1.5 mm, 2.0 mm, 2.5 mm, or 3.0 mm, or within any range bound by any two of those values (e.g., from 0.5 mm to 3.0 mm, from 0.8 mm to 2.5 mm, and so on). In other embodiments, the thickness 20 is less than 0.5 mm or greater than 3.0 mm. The cover substrate 10 further includes a bulk 22 within the thickness 20 at an approximate center volume of the cover substrate 10 at least approximately halfway within the thickness 20.

In embodiments, the cover substrate 10 includes a first compressive stress region 24, a second compressive stress region 26, and a tensile stress region 28. The first compressive stress region 24 extends from the first primary surface 12 inward into the thickness 20 to a depth of compression (“DOC”) 30. The second compressive stress region 26 extends from the second primary surface 14 inward into the thickness 20 to the DOC 30. The tensile stress region 28 is disposed between the first compressive stress region 24 and the second compressive stress region 26. In embodiments, the cover substrate 10 exhibits a compressive stress value of 300 MPa, 400 MPa, 500 MPa, 600 MPa, 700 MPa, 800 MPa, 900 MPa, 1000 MPa, 1100 MPa, 1200 MPa, 1300 MPa or within any range bound by any two of those values (e.g., from 300 MPa to 800 MPa, from 400 MPa to 700 MPa, and so on). In other embodiments, the cover substrate 10 exhibits a compressive stress value that is less than 300 MPa or greater than 1300 MPa. Compressive stress can be measured using those means known in the art, such as by surface stress meter (FSM) using commercially available instruments such as the FSM-6000, manufactured by Orihara Industrial Co., Ltd. (Japan). In embodiments, the bulk 22 of the cover substrate 10 is disposed within the tensile stress region 28.

As used herein, “depth of compression” or “DOC” refers to how far into the thickness 20 the first and second compressive stress regions 24, 26 extend, and is the depth into the thickness 20 at which the stress within the cover substrate 10 changes from compressive stress to tensile stress and has a stress value of zero. The DOC of the first and second compressive stress regions 24, 26 may be equivalent or have different values. The Compressive stress and tensile stress, being opposite, could be expressed as positive and negative values. Throughout this description, however, numerical values for both tensile stress and compressive stress are expressed as a positive or absolute value. DOC may be measured by FSM or a scattered light polariscope (SCALP) depending on the ion-exchange treatment. Where the stress in the cover substrate 10 is generated by exchanging potassium ions into the cover substrate 10, FSM is used to measure DOC. Where the stress is generated by exchanging sodium ions into the cover substrate 10, SCALP is used to measure DOC. Where the stress in the cover substrate 10 is generated by exchanging both potassium and sodium ions into the cover substrate 10, the DOC is measured by SCALP, since it is believed the exchange depth of sodium indicates the DOC and the exchange depth of potassium ions indicates a change in the magnitude of the compressive stress (but not the change in stress from compressive to tensile).

In embodiments, the DOC 30 of the cover substrate 10 is within a range of from 0.18t to 0.25t, where t is the thickness 20 of the cover substrate 10. The DOC 30, in various embodiments, can be greater than 80 μm. For example, the depth of compression 30 can be from 80 μm to 300 μm, from 100 μm to 250 μm, from 150 μm to 200 μm, or any and all sub-ranges formed from any of these endpoints.

As used herein, the terms “depth of layer” and “DOL” refer to the depth of the compressive layer as determined by surface stress meter (FSM) measurements using commercially available instruments such as the FSM-6000. Depth of layer (“DOL”) has been used as an approximate measure of the depth of penetration of the larger (strengthening) cation (e.g., K⁺ during K⁺ for Na⁺ exchange). In embodiments, the DOL of the cover substrate 10 is within a range of from 4 μm to 20 μm.

Maximum tensile stress or central tension (“CT”) values within the tensile stress region 28 are measured using a scattered light polariscope (“SCALP”) technique known in the art. In embodiments, the cover substrate 10 exhibits a CT of 10 MPa, 20 MPa, 30 MPa, 40 MPa, 50 MPa, 60 MPa, 70 MPa, 80 MPa, 90 MPa, 100 MPa, or within any range bound by any two of those values (e.g., from 10 MPa to 100 MPa, from 40 MPa to 70 MPa, and so on).

In embodiments, the cover substrate 10 includes a composition that is a glass composition or a glass-ceramic composition. The glass composition can be a soda lime glass composition, an alkali aluminosilicate glass composition, an alkali containing borosilicate glass composition, or an alkali aluminoborosilicate glass composition, among other options. The glass composition can be characterized as ion-exchangeable, meaning the composition is capable of exchanging cations located at or near the first and second primary surfaces 12, 14 with cations of the same valence that are either larger or smaller in size, thus forming the first and second compressive stress regions 24, 26 balanced by the tensile stress region 28.

In embodiments, the glass composition or glass-ceramic composition of the cover substrate 10 includes (on an oxide basis): greater than 50% by weight SiO₂; greater than 5% by weight Al₂O₃; and at least one of Li₂O and Na₂O. In embodiments, the glass composition or glass-ceramic composition of the cover substrate 10 includes (on an oxide basis): from 50% by weight to 80% by weight SiO₂; from 5% by weight to 35% by weight Al₂O₃; and at least one of Li₂O and Na₂O. In embodiments, the glass composition or glass-ceramic composition of the cover substrate 10 includes (on an oxide basis): greater than 50% by weight SiO₂; greater than 10% by weight Al₂O₃; greater than 1% by weight Li₂O; and greater than 5% by weight Na₂O. In embodiments, the composition of the cover substrate 10 further includes (on an oxide basis): greater than 1% by weight B₂O₃ and/or greater than 4% by weight P₂O₅. In embodiments, the glass composition or glass-ceramic composition of the cover substrate 10, at the bulk 22, includes (on an oxide basis): from 50% by weight to 70% by weight SiO₂; from 15% by weight to 30% by weight Al₂O₃; from 1.5% by weight to 8% by weight B₂O₃; and from 1% by weight to 15% by weight Na₂O. In embodiments, the glass composition or glass-ceramic composition of the cover substrate 10, at the bulk 22, includes (on an oxide basis): from 50% by weight to 80% by weight SiO₂; from 5% by weight to 25% by weight Al₂O₃; from 1% by weight to 10% by weight P₂O₅; and from 1% by weight to 15% by weight Li₂O. In embodiments, the glass composition includes one or more alkaline earth oxides, such that a content of alkaline earth oxides is at least 5 wt %. Suitable glass compositions, in some embodiments, further include at least one of K₂O, MgO, and CaO.

An example glass composition or glass-ceramic composition of the cover substrate 10 includes (on an oxide basis): from 70% by weight to 80% by weight SiO₂; from 5% by weight to 10% by weight Al₂O₃; from 0.5% by weight to 5% by weight P₂O₅; from 5% by weight to 15% by weight Li₂O; and from 1% by weight to 8% by weight ZrO 2. Another example glass composition or glass-ceramic composition of the cover substrate 10 includes (on an oxide basis): from 65% by weight to 77% by weight SiO₂; from 5% by weight to 10% by weight Al₂O₃; from 0.5% by weight to 5% by weight P₂O₅; from 5% by weight to 15% by weight Li₂O; from 1% by weight to 8% by weight ZrO₂; from greater than 0% by weight to 0.5% by weight Na₂O; and from greater than 0% by weight to 0.2% by weight Fe₂O₃. Another example glass composition or glass-ceramic composition of the cover substrate 10 includes (on an oxide basis): from 50% by weight to 60% by weight SiO₂; from 15% by weight to 30% by weight Al₂O₃; from 0.5% by weight to 5% by weight B₂O₃; from 2.5% by weight to 8% by weight P₂O₅; from 0.5% by weight to 5% by weight Li₂O; from 3% by weight to 15% by weight Na₂O; and from 0.1% by weight to 3% by weight ZnO. Another example glass composition or glass-ceramic composition of the cover substrate 10 includes (on an oxide basis): from 60% by weight to 75% by weight SiO₂; from 15% by weight to 30% by weight Al₂O₃; from 0.5% by weight to 5% by weight B₂O₃; from 0.5% by weight to 5% by weight Li₂O; from 0.5% by weight to 5% by weight Na₂O; from 0.1% by weight to 3% by weight MgO; from greater that 0% by weight to 0.2% by weight Fe₂O₃; and from 0.1% by weight to 3% by weight ZnO. Another example glass composition or glass-ceramic composition of the cover substrate 10 includes (on an oxide basis): from 50% by weight to 60% by weight SiO₂; from 20% by weight to 35% by weight Al₂O₃; from 3% by weight to 10% by weight B₂O₃; from 2% by weight to 10% by weight Li₂O; from 0.5% by weight to 5% by weight Na₂O; from 1% by weight to 5% by weight MgO; from greater that 0% by weight to 1% by weight K₂O; and from 0.1% by weight to 3% by weight CaO. Another example glass composition or glass-ceramic composition of the cover substrate 10 includes (on an oxide basis): from 55% by weight to 70% by weight SiO₂; from 15% by weight to 25% by weight Al₂O₃; from 1% by weight to 8% by weight B₂O₃; from 7% by weight to 20% by weight Na₂O; and from 0.5% by weight to 3% by weight MgO. Any of the aforementioned compositions can further include SnO₂ or another fining agent. Any of the aforementioned compositions, unless stated otherwise, can be substantially free of Li₂O. The stated weight percentages can be the weight percentages of the glass composition that is subsequently cerammed to a glass-ceramic composition.

Examples of suitable glass-ceramic compositions for the cover substrate 10 include Li₂O—Al₂O₃—SiO₂ system (i.e., LAS-System) glass-ceramics, MgO—Al₂O₃—SiO₂ system (i.e., MAS-System) glass-ceramics, and glass-ceramic compositions including crystalline phases of any one or more of mullite, spinel, α-quartz, β-quartz solid solution, petalite, lithium disilicate, β-spodumene, nepheline, and alumina, and combinations thereof.

In embodiments, the composition of the cover substrate 10 as described above is the composition at the bulk 22 of the cover substrate 10, which is least influenced compositionally by any subsequent ion-exchange process.

In embodiments, the composition of the cover substrate 10 has a greater weight percentage of sodium ions or Na₂O and/or potassium ions or K₂O at or near one or both of the first primary surface 12 and the second primary surface 14 of the cover substrate 10 than at or near the bulk 22 of the cover substrate 10. The weight percentages of the constituents of the cover substrate 10 can be determined via spectroscopy, such as flame optical emission spectroscopy, inductively coupled plasma optical emission spectroscopy, or inductively coupled plasma mass spectroscopy.

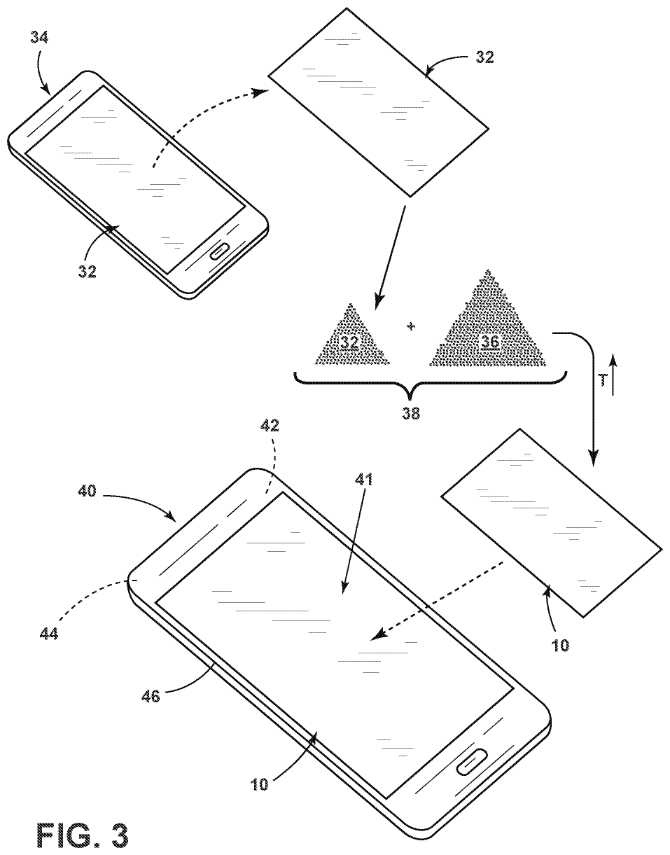

Referring now additionally to FIG. 3, the cover substrate 10, as alluded to above, includes post-consumer recycled cover substrate 32. In other words, the post-consumer recycled cover substrate 32 is removed from a used consumer electronic device 34 into which the post-consumer recycled cover substrate 32 was incorporated. The post-consumer recycled cover substrate 32 is subsequently combined as a raw material with other raw materials 36 to form total raw materials 38, melted, and formed again into the cover substrate 10 to be incorporated anew into an electronic device 40. Aspects of manufacturing the cover substrate 10 with the post-consumer recycled cover substrate 32, as well as the electronic device 40, are further discussed below.

In embodiments, the cover substrate 10 includes greater than or equal to 1% by weight post-consumer recycled cover substrate 32. In other words, of the total raw materials 38 utilized to manufacture the cover substrate 10, greater than or equal to 1% by weight of the total raw materials 38 is post-consumer recycled cover substrate 32. In embodiments, the cover substrate 10 includes 1%, 2%, 3%, 4%, 5%, 6%, 7%, 8%, 9%, 10%, 15%, 20%, 25%, 30%, or 35%, or any range bound by any two of those values (e.g., from 1% to 10%, from 1% to 20%, from 4% to 6%, from 2% to 20%, and so on), post-consumer recycled cover substrate 32.

In embodiments, the cover substrate 10 exhibits an axial transmission of greater than 90% for a wavelength of electromagnetic radiation within the visible region. In embodiments, the cover substrate 10 exhibits an axial transmission of greater than 90% for all wavelengths of electromagnetic radiation within the visible region. In embodiments, the cover substrate 10 exhibits an axial transmission of greater than 90% for a wavelength of electromagnetic radiation within a range of from 400 nm to 725 nm, or a range of from 420 nm to 800 nm. In embodiments, the cover substrate 10 exhibits an axial transmission of greater than 90% for all wavelength of electromagnetic radiation within a range of from 400 nm to 725 nm, or a range of from 420 nm to 800 nm. In embodiments, the cover substrate 10 exhibits an axial transmission that is greater than 90% for (i) electromagnetic radiation having a wavelength of 400 nm, (ii) electromagnetic radiation having a wavelength of 550 nm, and (iii) electromagnetic radiation having a wavelength of 725 nm. In embodiments, the cover substrate 10 exhibits an axial transition of less than or equal to 90% or less than or equal to 80%, for wavelengths of electromagnetic radiation within the visible region. The axial transmission can be determined via a spectrophotometer, using techniques known in the art.

In embodiments, the cover substrate 10 is a component of the electronic device 40. The electronic device 40 may include a housing 42 having a back surface 44, and side surfaces 46. The electronic device 40 further includes electrical components (not shown) that the housing 42 at least partially houses including at least a controller, a memory, and a display 41 at or adjacent to the front surface of the housing 42. The cover substrate 10 covers the display and may provide a front surface of the electronic device 40. The electronic device 40 can be a consumer electronic device 40, such as a smart phone, a tablet, a music or video playing device, and so on.

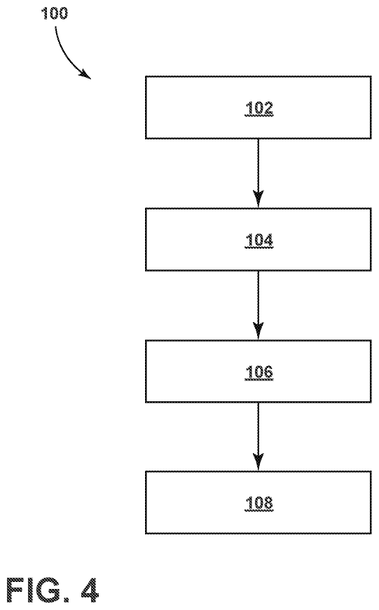

Referring now to FIG. 4, a method 100 of manufacturing the cover substrate 10 includes, at a step 102, preparing a batch (of total raw materials 38) comprising one or more glass-forming oxides, as the new raw materials 36, and greater than 1% by weight of post-consumer recycled cover substrate 32. In embodiments, the batch includes 1%, 2%, 3%, 4%, 5%, 6%, 7%, 8%, 9%, 10%, 15%, 20%, 25%, 30%, or 35%, or any range bound by any two of those values (e.g., from 1% to 10%, from 4% to 6%, from 2% to 20% and so on), by weight post-consumer recycled cover substrate 32. In other embodiments, the batch includes greater than 35% by weight of post-consumer recycled cover substrate 32. The post-consumer recycled cover substrate 32 may be powderized before combining the post-consumer recycled cover substrate 32 with new raw materials 36 of sources of the one or more oxides to form the batch. The post-consumer recycled cover substrate 32 can have a glass composition or glass-ceramic composition, as described above for the cover substrate 10.

At a step 104, the method 100 further includes, forming the cover substrate 10 from the batch. In embodiments, the cover substrate 10 is a glass composition that is formed from the batch via fusion draw processes, slot draw processes, thin rolling processes, float processes, or a combination thereof.

The fusion draw process, for example, uses a drawing tank that has a channel for accepting molten material (e.g., the total raw materials 38 in a molten state). The channel has weirs that are open at the top along the length of the channel on both sides of the channel. When the channel fills with molten material, the molten glass overflows the weirs. Due to gravity, the molten glass flows down the outside surfaces of the drawing tank as two flowing glass films. These outside surfaces of the drawing tank extend down and inwardly so that they join at an edge below the drawing tank. The two flowing glass films join at this edge to fuse and form a single flowing glass material that, when cooled and further processed, becomes the cover substrate 10. The fusion draw process offers the advantage that, because the two glass films flowing over the channel fuse together, neither of the outside surfaces of the resulting glass material comes in contact with any part of the apparatus. Thus, the surface properties of the fusion drawn glass material are not affected by such contact.

The slot draw process is distinct from the fusion draw process. In slot draw processes, the molten raw material is provided to a drawing tank. The bottom of the drawing tank has an open slot with a nozzle that extends the length of the slot. The molten glass flows through the slot/nozzle and is drawn downward as a continuous material and into an annealing region.

Such down-draw processes produce glass materials having a uniform thickness that possess relatively pristine surfaces. Because the average flexural strength of glass materials is controlled by the amount and size of surface flaws, a pristine surface that has had minimal contact has a higher initial strength. When this high strength glass material is then further strengthened (e.g., via ion-exchange), the resultant strength can be higher than that of a glass material with a surface that has been lapped and polished. Down-drawn glass materials may be drawn to a thickness of less than about 2 mm. In addition, down-drawn glass materials have a very flat, smooth surface that can be used in its final application without costly grinding and polishing.

The thin rolling process may be that described in U.S. Pat. Nos. 8,713,972, 9,003,835, U.S. Patent Publication No. 2015/0027169, and U.S. Patent Publication No. 20050099618, the contents of which are incorporated herein by reference in their entirety. More specifically, a vertical stream of molten glass is supplied into a pair of forming rolls, maintained at a surface temperature of about 500° C. or higher or about 600° C. or higher, to form a formed glass ribbon having a formed thickness, sizing the formed glass ribbon with a pair of sizing rolls, maintained at a surface temperature of about 400° C. or lower, to produce a sized glass ribbon having a desired thickness less than the formed thickness and a desired thickness consistency. The apparatus used to form the glass ribbon may include a glass feed device for supplying the vertical stream of molten glass to the pair of forming rolls. The forming rolls are spaced closely adjacent to each other, defining a glass forming gap between the forming rolls with the glass forming gap located vertically below the glass feed device for receiving the supplied stream of molten glass and thinning the supplied stream of molten glass between the forming rolls to form the formed glass ribbon. The sizing rolls are spaced closely adjacent to each other, defining a glass sizing gap between the sizing rolls with the glass sizing gap located vertically below the forming rolls for receiving the formed glass ribbon and thinning the formed glass ribbon to produce the sized glass ribbon having.

In some instances, the thin rolling process may be utilized where the viscosity of the glass does not permit use of fusion or slot draw methods. For example, thin rolling can be utilized to form the glass or glass-ceramic articles when the glass exhibits a liquidus viscosity of less than 100 kP. The glass or glass-ceramic article may be acid polished or otherwise treated to remove or reduce the effect of surface flaws.

Float glass processes produce glass materials that may be characterized by smooth surfaces and uniform thickness. In a float glass process, the glass material is made by floating molten glass on a bed of molten metal, typically tin. In an example process, molten glass that is fed onto the surface of the molten tin bed forms a floating glass ribbon. As the glass ribbon flows along the tin bath, the temperature is gradually decreased until the glass ribbon solidifies into a solid glass material that can be lifted from the tin onto rollers. Once off the bath, the glass material can be cooled further and annealed to reduce internal stress.

In embodiments, at a step 106, the method 100 further includes tempering the cover substrate 10 resulting in the first compressive stress region 24 and, in embodiments, the second compressive stress region 26. In other words, the cover substrate 10 is “strengthened.” In embodiments, the cover substrate 10 is thermally tempered. In other embodiments, the cover substrate 10 is chemically tempered via subjecting the cover substrate 10 to an ion-exchange process. In some embodiments, the cover substrate 10 may be strengthened using a combination of chemical tempering processes and thermally tempering processes.

In thermal tempering, the cover substrate 10 is heated to an elevated temperature above the glass transition temperature of the glass composition and then the first and second primary surfaces 12, 14 of the cover substrate 10 are rapidly cooled (“quenched”) while the inner regions (e.g., the bulk 22) of the cover substrate 10 cool at a slower rate. The inner regions cool more slowly because they are insulated by the thickness 20 and the fairly low thermal conductivity of the cover substrate 10. The differential cooling produces the first and second compression stress regions 24, 26 contiguous with the first and second primary surfaces 12, 14, respectively, balanced by the tensile stress region 28 encompassing the bulk 22 of the cover substrate 10.

In an ion-exchange process, typically by immersion of the cover substrate 10 (having a glass composition or glass-ceramic composition) into a molten salt bath for a predetermined period of time, ions at or near the first and second primary surfaces 12, 14 of the glass or glass-ceramic composition are exchanged for larger metal ions from the salt bath. In embodiments, the temperature of the molten salt bath is in the range of from about 300° C. to about 500° C., such as from about 400° C. to about 460° C., and the predetermined time period is within a range of from about 1 hour to about 64 hours, such as from about 4 hours to about 24 hours. However, the temperature and duration of immersion may vary according to the composition of the material and the desired strength attributes. The incorporation of the larger ions into the glass or glass-ceramic composition strengthens the composition by creating the first compressive stress region 24 and the second compressive stress region 26 contiguous with or adjacent to the first primary surface 12 and the second primary surface 14, respectively. The tensile stress region 28 is additionally induced to balance the compressive stress regions.

In one example, sodium ions in the cover substrate 10 are replaced by larger potassium ions from the molten bath, such as a potassium nitrate salt bath, though other alkali metal ions having larger atomic radii, such as rubidium or cesium, and can replace smaller alkali metal ions in the glass. As a result, in embodiments, after ion-exchange, the weight percentage of potassium ions in the composition of the cover substrate 10 at or near the first primary surface 12 and the second primary surface 14 is greater than the weight percentage of potassium ions at or near the bulk 22 of the cover substrate 10. Similarly, in embodiments, after ion-exchange, the weight percentage of sodium ions in the composition of the cover substrate 10 at or near the first primary surface 12 and the second primary surface 14 is less than the weight percentage of sodium ions at or near the bulk 22 of the cover substrate 10.

According to particular embodiments, smaller alkali metal ions in the cover substrate 10 can be replaced by Ag⁺ ions. Similarly, other alkali metal salts, such as, but not limited to, sulfates, phosphates, halides, and the like, may be used in the ion-exchange process.

The replacement of smaller ions by larger ions at a temperature below that at which the glass network can relax produces a distribution of ions across the first primary surface 12 and second primary surface 14 of the cover substrate 10 that results in a stress profile. The larger volume of the incoming ions produces the first and second compressive stress regions 24, 26 and the tensile stress region 28.

At a step 108, the method 100 can further include ceramming the cover substrate 10 formed from the target batch. The step 108 of ceramming can occur before or after the step 106 of tempering the cover substrate 10. Ceramming transforms a cover substrate 10 with a glass composition into a cover substrate 10 with a glass-ceramic composition. Glass-ceramics are polycrystalline materials formed by a controlled crystallization of a precursor glass, here the cover substrate 10 with a glass composition. Such materials may be produced by melting a glass-forming batch containing selected metal oxides, cooling the melt to a temperature below its transformation range while forming a glass body in a desired geometry, and heating the glass body above the transformation range of the glass in a controlled manner (i.e., “ceramming”) to generate crystals in situ. Such heating in a controlled manner may include subjecting the glass composition to one or more elevated temperatures (e.g., from about 500° C. to about 1100° C.) for one or more preset periods of time.

In embodiments, the post-consumer recycled cover substrate 32 had been subjected to an ion-exchange process. In other words, before being incorporated into the used consumer electronic device 34 and being used throughout the life of the used consumer electronic device 34, the post-consumer recycled cover substrate 32 was initially a cover substrate that was subjected to an ion-exchange process in order to strengthen the cover substrate for use with the used consumer electronic device 34. Like the cover substrate 10, the post-consumer recycled cover substrate 32 (before being recycled) included a first primary surface (not separately illustrated), a second primary surface, and a bulk between the first and second primary surfaces. As a consequence of the ion-exchange process, the composition of the post-consumer recycled cover substrate 32 (before being recycled) had a greater percentage of an alkali oxide at or near the first and second primary surfaces than at the bulk.

In embodiments, except for alkali oxides, the composition of the cover substrate 10 formed via the method 100 is substantially the same as the composition of the post-consumer recycled cover substrate 32. For example, the weight percentages (on an oxide basis) of glass-forming oxides, such as SiO₂, Al₂O₃, and at least one of B₂O₃, and P₂O₅, in the cover substrate 10 formed via the method 100 differ by 1% by weight or less from the weight percentages (on an oxide basis) of the same glass-forming oxides, such as of SiO₂, Al₂O₃, and the at least one of B₂O₃ and P₂O₅, in the post-consumer recycled cover substrate 32. However, because of the ion-exchange process that the post-consumer recycled cover substrate 32 underwent before its serviceable life, the weight percentages (on an oxide basis) of one or more alkali oxides in the composition of the post-consumer recycled cover substrate 32 can be different than the weight percentages of the one or more alkali oxides (e.g., the new raw materials 36) used to form the batch (e.g., the total raw materials 38) at the step 102 of the method 100 and in the composition of the cover substrate 10 formed therefrom.

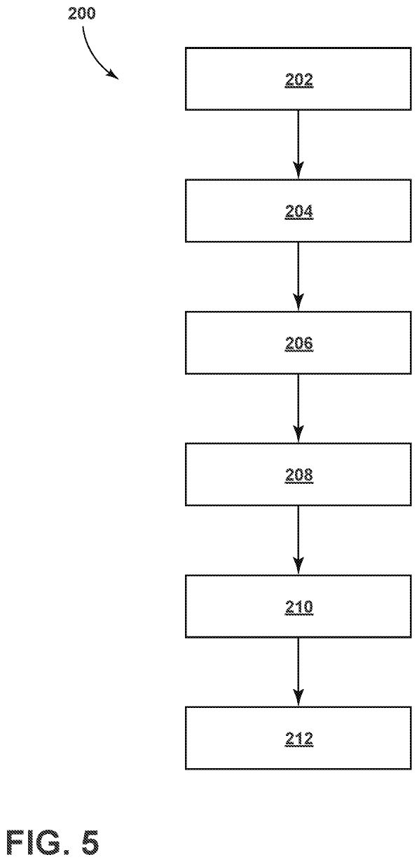

Referring now to FIG. 5, a method 200 of manufacturing the cover substrate 10, at a step 202, includes determining the composition of the post-consumer recycled cover substrate 32 (hereinafter, the “recycled composition”). When the recycled composition of the post-consumer recycled cover substrate 32 is a glass composition or glass-ceramic composition including SiO₂ and one or more alkali oxides, the recycled composition can be determined via spectroscopy, such as flame optical emission spectroscopy, inductively coupled plasma optical emission spectroscopy, or inductively coupled plasma mass spectroscopy.

At a step 204, the method 200 further includes determining a maximum weight percentage of the post-consumer recycled cover substrate 32 that can be added to a predetermined batch (e.g., new raw materials 36) comprising a predetermined composition to form a target batch (e.g., total raw materials 38) that includes a target composition, without a weight percentage of any component of the target composition exceeding a predetermined limit. The target batch (e.g., the total raw materials 38) with the target composition is also predetermined so as to produce the cover substrate 10 that meets the desired specifications (e.g., desired axial transmission, ability to be ion-exchanged, and so on). The target composition includes at least SiO₂ and other oxides as necessary to form any of the embodiments of the cover substrate 10 described above. The predetermined composition of the predetermined batch (e.g., the new raw materials 36) and recycled composition of the post-consumer recycled cover substrate 32 also include SiO₂. In embodiments, the target batch (e.g., the total raw materials 38) includes greater than or equal to 1% by weight of the post-consumer recycled cover substrate 32 and balance weight percentage of the predetermined batch (e.g., the new raw materials 36). In embodiments, the target batch (e.g., the total raw materials 38) includes (by weight) 1%, 2%, 3%, 4%, 5%, 6%, 7%, 8%, 9%, 10%, 11%, 12%, 13%, 14%, 15%, 16%, 17%, 18%, 19%, or 20% of the post-consumer recycled cover substrate 32 and balance weight percentage of the predetermined batch (e.g., the new raw materials 36), or any range bound by any two of those values (e.g., from 4% by weight to 6% by weight, from 2% by weight to 20% by weight, from 1% by weight to 20% by weight, and so on) of the post-consumer recycled cover substrate 32 and balance weight percentage of the predetermined batch (e.g., the new raw materials 36).

As mentioned, the target composition of the target batch (e.g., the total raw materials 38) typically has tight specifications in terms of the weight percentages of the constituents, because minor variations in the target composition can majorly affect the properties and performance of the cover substrate 10 formed therefrom. In embodiments, the predetermined composition of the predetermined batch (e.g., the new raw materials 36) and the target composition of the target batch (e.g., the total raw materials 38) are the same or about the same. As a consequence, the predetermined batch (e.g., the new raw materials 36) could be utilized alone and without the addition of the post-consumer recycled cover substrate 32 to form the cover substrate 10 with the desired specifications. In such instances, the post-consumer recycled cover substrate 32, if also sufficiently similar in composition to the target composition, can be added to the predetermined batch (e.g., the new raw materials 36) without the combination deviating from the target composition.

Stated another way, the target composition of the target batch (e.g., the total raw materials 38), although having tight specifications, can have some tolerance for deviation of the weight percentage of any of the one or more oxides used to form the target batch. For example, the target composition might call for 10 wt % Na₂O but allow for a tolerance of ±0.2 wt %. In some instances, the predetermined composition of the predetermined batch (e.g., the new raw materials 36) can be 10 wt % Na₂O. Thus, the predetermined batch can be utilized alone and without the addition of the post-consumer recycled cover substrate 32 and still generate the target batch (e.g., the total raw materials 38) with the target composition. Because of the small but existing tolerance for the weight percentage of Na₂O, even if the recycled composition of the post-consumer recycled cover substrate 32 includes, for instance 11 wt % Na₂O, a weight percentage up to a maximum weight percentage of the post-consumer recycled cover substrate 32 could be combined with the predetermined batch (e.g., the new raw materials 36) and still produce the target batch (e.g., the total raw materials 38) with the target composition, for instance with 10.2 wt % Na₂O. The maximum weight percentage of the post-consumer recycled cover substrate 32 is the value that, when combined with the predetermined batch (e.g., the new raw materials 36), results in the target composition of the target batch but, if exceeded, does not result in the target composition of the target batch.

At a step 206, the method 200 further includes combining the maximum weight percentage of the post-consumer recycled cover substrate 32, as determined at step 204, or less, with the predetermined batch (e.g., the new raw materials 36). The combination of the maximum weight percentage of the post-consumer recycled cover substrate 32, or less, and the predetermined batch (e.g., the new raw materials 36) forms the target batch (e.g., the total raw materials).

At a step 208, the method 200 further includes forming the cover substrate 10 from the target batch. The cover substrate 10 can be formed via any of the formation processes described above. The post-consumer recycled cover substrate 32 and the predetermined batch (e.g., the new raw materials 36) are melted together as the target batch (e.g., the total raw materials 38) to a molten state, and the cover substrate 10 is formed therefrom.

At a step 210, the method 200 further includes subjecting the cover substrate 10 so formed at step 208 to a tempering process, such as an ion-exchange process. The prior discussion related to tempering applies equally to the step 210.

At a step 212, the method 200 further includes ceramming the cover substrate 10 formed from the target batch. The prior discussion related to ceramming applies equally to the step 210.

In embodiments, the recycled composition of the post-consumer recycled cover substrate 32 and the target composition of the target batch (e.g., the total raw materials 38) both include a weight percentage of Na₂O while the predetermined batch (e.g., the new raw materials 36) does not include any intentionally added Na₂O. For example, although the predetermined batch (e.g., the new raw materials 36) does not include any intentionally added Na₂O, it may be assumed that the Na₂O is introduced during manufacturing of the cover substrate 10 as a tramp material from other raw materials or processing equipment. Accordingly, the predetermined batch (e.g., the new raw materials 36) can be utilized without incorporation of the post-consumer recycled cover substrate 32 and the target batch (e.g., the total raw materials 38) will still include the requisite amount of Na₂O. Further, because the target batch (e.g., the total raw materials 38) allows for an upper limit of Na₂O, additional Na₂O brought in via incorporation of the post-consumer recycled cover substrate 32, when combined with the predetermined batch (e.g., the new raw materials 36), can still result in the target batch with a tolerable amount of Na₂O. Again, the maximum weight percentage of the post-consumer recycled cover substrate 32 that results in the weight percentage of Na₂O of the target batch (e.g., the total raw materials 38) falling within the prescribed tolerance can be determined.

In embodiments, the predetermined composition of the predetermined batch (e.g., the new raw materials 36) includes a weight percentage of Na₂O intentionally added, while the recycled composition includes a weight percentage of Na₂O that is greater than the weight percentage to be added with the predetermined batch (e.g., the new raw materials 36). In other words, in these embodiments, the Na₂O is not assumed to come only from tramp, if the predetermined batch (e.g., the new raw materials 36) is utilized alone to form the target batch (e.g., the total raw materials 38), and may also come from the predetermined batch (e.g., the new raw materials 36) and the post-consumer recycled cover substrate 32 if included.

In embodiments, both the recycled composition of the post-consumer recycled cover substrate 32 and the predetermined composition of the predetermined batch (e.g., the new raw materials 36) include K₂O. In embodiments, the recycled composition has a weight percentage of K₂O that is greater than a weight percentage of K₂O in the predetermined composition. The recycled composition having a greater weight percentage of K₂O can be a consequence of the post-consumer recycled cover substrate 32 having underwent an ion-exchange process.

In embodiments, the recycled composition of the post-consumer recycled cover substrate 32 and the predetermined composition of the predetermined batch (e.g., the new raw materials 36) include Li₂O. In embodiments, the recycled composition has a weight percentage of Li₂O that is less than a weight percentage of Li₂O in the predetermined composition. The recycled composition having a lesser weight percentage of Li₂O can be a consequence of the post-consumer recycled cover substrate 32 having underwent an ion-exchange process.

In embodiments, the weight percentages (on an oxide basis) of SiO₂, Al₂O₃, B₂O₃, and P₂O₅ of the target composition of the target batch (e.g., the total raw materials 38) differ by 1% by weight or less from weight percentages (on an oxide basis) of SiO₂, Al₂O₃, B₂O₃, and P₂O₅ in the recycled composition of the post-consumer recycled cover substrate 32. The closer the recycled composition of the post-consumer recycled cover substrate 32 is to the target composition of the target batch (e.g., the total raw materials 38), the greater the weight percentage of the post-consumer recycled cover substrate 32 that the target batch (e.g., the total raw materials 38) can include and remain within specifications.

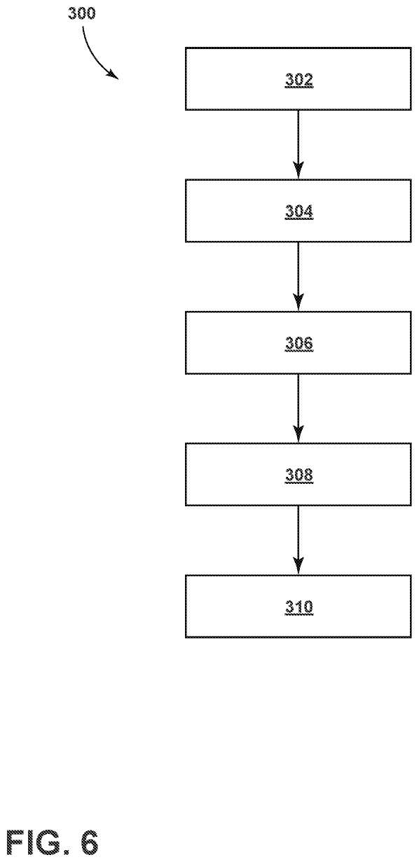

Referring now to FIG. 6, a method 300 of manufacturing the cover substrate 10 includes, at a step 302, determining the recycled composition of the post-consumer recycled cover substrate 32. The recycled composition includes one or more oxides, such as SiO₂, Al₂O₃, and so on. The discussion for step 202 of the method 200 applies equally to step 302.

At a step 304, the method 300 further includes determining the target composition of the target batch (e.g., the total raw materials 38) that is to be utilized to form the cover substrate 10. The target composition is that composition thought to produce the cover substrate 10 with the desired properties. The target composition may be target weight percentages of one or more oxides, such as SiO₂, B₂O₃, Al₂O₃, Na₂O, Li₂O, ZnO, P₂O₅, and so on.

At a step 306, the method 300 further includes determining a desired weight percentage of the post-consumer recycled cover substrate 32 in the cover substrate 10. As discussed, in embodiments, the desired weight percentage can be greater than 1%, such as 1%, 2%, 3%, 4%, 5%, 6%, 7%, 8%, 9%, 10%, 11%, 12%, 13%, 14%, 15%, 16%, 17%, 18%, 19%, or 20%, or any range bound by any two of those values (e.g., from 4% to 6%, from 2% to 20%, from 1% to 20%, and so on). In other embodiments, the desired weight percentage is greater than 20%, such as greater than 30% or more. The desired weight percentage may be driven by the specifications of a manufacturer of the electronic device 40, which then advertises the cover substrate 10 utilized in the electronic device 40 as containing a certain percentage of post-consumer recycled content.

At a step 308, the method 300 further includes determining a remediating composition of a remediating batch (e.g., new raw materials 36). The remediating batch (e.g., the new raw materials 36), when combined with the desired weight percentage of the post-consumer recycled cover substrate 32, forms the target batch (e.g., the total raw materials 38) having the target composition. For example, if (a) the recycled composition is 70% by weight SiO₂, 15% by weight Al₂O₃, and 15% by weight Na₂O, (b) the target composition is 72% by weight SiO₂, 17% by weight Al₂O₃, and 11% by weight Na₂O, and (c) the desired weight percentage of the post-consumer recycled cover substrate 32 in the cover substrate 10 is 5% by weight, then the remediating composition of the remediating batch (being 95% by weight of the target batch) would be 72.1% by weight SiO₂, 17.1% by weight Al₂O₃, and 10.8% by weight Na₂O. The remediating composition balances the recycled composition to achieve the target composition.

At a step 308, the method 300 further includes forming the target batch (e.g., the total raw materials 38) with the desired weight percentage of the post-consumer recycled cover substrate 32 and a remaining weight percentage of the remediating batch (e.g., the new raw materials 36). The desired weight percentage of the post-consumer recycled cover substrate 32 and the remediating weight percentage of the remediating batch (e.g., the new raw materials 36) can be combined together to form the target batch (e.g., the total raw materials 38) and thereafter melted together into a molten state.

At a step 310, the method 300 further includes forming the cover substrate 10 from the target batch (e.g., the total raw materials 38). The formation can be via any of the glass and glass-ceramic formation processes previously described. In embodiments, both the post-consumer recycled cover substrate 32 and the cover substrate 10 are glasses or glass-ceramics.

As long as all of the constituents of the recycled composition are also in the target composition, the method 300 can accommodate relatively large weight percentages for the desired weight percentage of the post-consumer recycled cover substrate 32. The closer the recycled composition is to the target composition, the higher the desired weight percentage can be and less weight percentage of the remediating batch (e.g., new raw materials 36) will be required to balance the recycled composition to achieve the target composition.

The methods 100, 200, 300, and the examples below, demonstrate that cover substrates of consumer electronic devices can be recycled after consumer use and incorporated into new cover substrates 10, with the cover substrates 10 still satisfying performance specifications. Contrary to conventional wisdom, this is true even when the recycled content has been subjected to an ion-exchange process. The incorporation of the post-consumer recycled cover substrate 32 into new cover substrates 10 will reduce raw material and energy consumption. In particular, the expense associated with obtaining new lithium sources (e.g., lithium carbonate and spodumene), which are in declining availability, can be reduced.

### EXAMPLES

### Example 1

For Example 1, post-consumer recycled cover substrate having a glass composition that had been subjected to an ion-exchange process was obtained and crushed. The composition of the post-consumer recycled cover substrate was determined via inductively coupled plasma optical emission and fire emission spectroscopy to include (by weight) 56.3% SiO₂, 22.5% Al₂O₃, 9.08% Na₂O, 5.28% P₂O₅, 2.39% B₂O₃, 2.30% Li₂O, 1.47% ZnO, 0.13% SnO₂, 1000 ppm K₂O, and balance trace oxides.

Two batches were prepared—(i) a first batch (“Batch 1”) including 5% by weight of the post-consumer recycled cover substrate and balance by weight of a predetermined composition and (ii) a second batch (“Batch 2”) including only the predetermined composition. The predetermined composition included (by weight) 56.84% SiO₂, 22.8% Al₂O₃, 8.49% Na₂O, 5.32% P₂O₅, 2.62% Li₂O, 2.33% B₂O₃, 1.45% ZnO, 0.0069% K₂O, and balance various other oxides. Note that the composition of the post-consumer recycled cover substrate included a greater weight percentage of Na₂O and K₂O than the predetermined composition but a lesser weight percentage of Li₂O than the predetermined composition. The difference in composition is a consequence of the ion-exchange process that the post-consumer recycled cover substrate underwent before commencing its useful life as a component of a consumer electronic device. Due to the inclusion of the post-consumer recycled cover substrate, the first batch included a slightly greater weight percentage of Na₂O and K₂O but less weight percentage of Li₂O than the second batch, but still within acceptable tolerances compared to target weight percentages for those constituents.

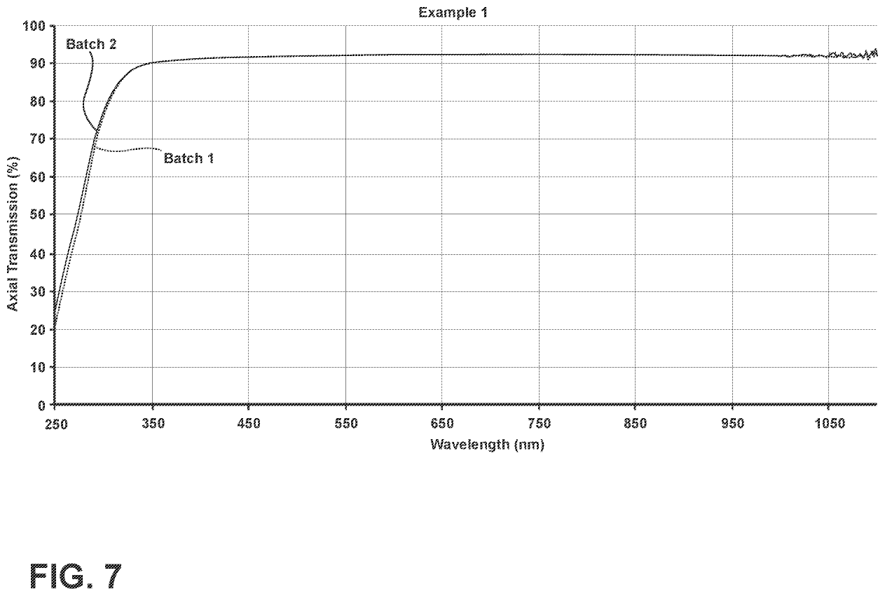

Both batches were melted in a lab environment and formed into glass sheets having a thickness of 0.6 mm. The axial transmission of the glass sheets that formed both batches was measured. The results are illustrated in graphical form at FIG. 7, with the percentage axial transmission as a function of wavelength of electromagnetic radiation plotted. There are no significant differences in axial transmission between the two batches.

Next both glass sheets were subjected to an identical ion-exchange process. The resulting compressive and tensile stresses that each glass sheet exhibited were measured. The glass sheet made from Batch 1 with the post-consumer recycled cover substrate exhibited, on average, a compressive stress of about 1253 MPa and a central tension of about 61.3 MPa. The glass sheet made from Batch 2 without any recycled material exhibited, on average, a compressive stress of about 1249 MPa and a central tension of about 61.9 MPa. Despite the inclusion of greater weight percentages of Na₂O and K₂O but less weight percentage of Li₂O than the second batch, the ion-exchange process generated approximately the same compressive and tensile stresses in the glass sheet made from Batch 1.

In addition, the depth of layer and depth of compression resulting from the ion-exchange process were measured for both glass sheets. The depth of layer for the glass sheet from Batch 1 with the post-consumer recycled cover substrate and for the glass sheet from Batch 2 were both, on average, about 5.9 μm. On average, the depth of compression for the glass sheet from Batch 1 was about 114 μm, while the depth of compression for the glass sheet from Batch 2 was about 115 μm. Despite the inclusion of greater weight percentages of Na₂O and K₂O but less weight percentage of Li₂O than the second batch, the ion-exchange process generated approximately the same depth of compression and depth of layer in the glass sheet made from Batch 1.

What is claimed is:

1. A cover substrate for an electronic device comprising:
greater than or equal to 1% by weight post-consumer recycled cover substrate.

2. The cover substrate of claim 1 further comprising:
a first primary surface;
a second primary surface that faces in a generally opposite direction as the first primary surface; and
a thickness between the first primary surface and the second primary surface, the thickness being within a range of from 0.05 mm to 3.0 mm.

3. The cover substrate of claim 1 further comprising:
a composition comprising (on an oxide basis):
greater than 50% by weight SiO₂;
greater than 5% by weight Al₂O₃; and
at least one of Li₂O and Na₂O.

4. The cover substrate of claim 1 further comprising:
(i) a bulk and (ii) a composition at the bulk that comprises (on an oxide basis):
from 50% by weight to 70% by weight SiO₂;
from 15% by weight to 30% by weight Al₂O₃;
from 1.5% by weight to 8% by weight B₂O₃; and
from 1% by weight to 15% by weight Na₂O.

5. The cover substrate of claim 1 further comprising:
a glass composition or a glass-ceramic composition,
wherein, the post-consumer recycled cover substrate comprises a glass composition or a glass-ceramic composition.

6. The cover substrate of claim 1, wherein
the cover substrate comprises a compressive stress region; and
the cover substrate comprises a composition that has a greater weight percentage of sodium ions at or near a primary surface of the cover substrate than at or near a bulk of the cover substrate.

7. The cover substrate of claim 1, wherein
the cover substrate exhibits an axial transmission of greater than 90% for a wavelength of electromagnetic radiation within the range of 420 nm to 800 nm.

8. The cover substrate of claim 1, wherein
the cover substrate comprises from 2% by weight to 20% by weight post-consumer recycled cover substrate.

9. A method of manufacturing a cover substrate of an electronic device comprising:
preparing a batch comprising one or more glass-forming oxides and greater than 1% by weight of post-consumer recycled cover substrate; and
forming a cover substrate from the batch.

10. The method of claim 9 further comprising:
tempering the cover substrate resulting in the cover substrate comprising a compressive stress region.

11. The method of claim 9 further comprising:
ceramming the cover substrate to form the cover substrate comprising a glass-ceramic composition.

12. The method of claim 9, wherein
the post-consumer recycled cover substrate had been subjected to an ion-exchange process before the batch was prepared; and
the post-consumer recycled cover substrate, before the batch is prepared, comprises (i) a first primary surface, a second primary surface, and a bulk disposed between the first primary surface and the second primary surface and (ii) a composition that comprises an alkali oxide that is a greater percentage of the composition at or near the first primary surface than at the bulk.

13. The method of claim 9, wherein
the batch comprises from 2% by weight to 20% by weight of the post-consumer recycled cover substrate;
the cover substrate comprises a glass composition or a glass-ceramic composition; and
the post-consumer recycled cover substrate comprises a glass composition or a glass-ceramic composition.

14. A method of manufacturing a cover substrate of an electronic device comprising:
determining a recycled composition of a post-consumer recycled cover substrate, the recycled composition comprising SiO₂ and one or more alkali oxides;
determining a maximum weight percentage of the post-consumer recycled cover substrate that can be added to a predetermined batch comprising a predetermined composition, the predetermined composition comprising SiO₂, to form a target batch comprising a target composition comprising SiO₂ and one or more alkali oxides, without a weight percentage of any component of the target composition exceeding a predetermined limit;
combining the maximum weight percentage or less of the post-consumer recycled cover substrate with the predetermined batch thus forming the target batch; and
forming a cover substrate from the target batch.

15. The method of claim 14 further comprising:
subjecting the cover substrate formed from the target batch to an ion-exchange process,
wherein, the cover substrate after the ion-exchange procedure comprises (i) a compressive stress region and (ii) a composition that has a greater weight percentage of potassium ions at or near a primary surface of the cover glass than at or near a bulk of the cover substrate.

16. The method of claim 14 further comprising:
ceramming the cover substrate formed from the target batch.

17. The method of claim 14, wherein
the one or more alkali oxides of the recycled composition comprises a weight percentage of Na₂O;
the predetermined composition of the predetermined batch comprises a weight percentage of Na₂O; and
the weight percent of Na₂O of the recycled composition is greater than the weight percentage of Na₂O of the predetermined composition.

18. The method of claim 14, wherein
the one or more alkali oxides of the recycled composition and the one or more alkali oxides of the predetermined composition both comprise Li₂O; and
the recycled composition has a weight percentage of Li₂O that is less than a weight percentage of Li₂O in the predetermined composition.

19. The method of claim 14, wherein
the target batch comprises greater than or equal to 1% by weight of the post-consumer recycled cover substrate.

20. The method of claim 14, wherein
weight percentages (on an oxide basis) of SiO₂, Al₂O₃, and at least one of B₂O₃ and P₂O₅ of the target composition differ by 1% by weight or less from weight percentages (on an oxide basis) of SiO₂, Al₂O₃, and the at least one of B₂O₃ and P₂O₅ in the recycled composition of the post-consumer recycled cover substrate.
